(19) United States
(12) Patent Application Publication
(10) Pub. No.: US 2025/0015048 A1
(43) Pub. Date: Jan. 9, 2025

(54) SEMICONDUCTOR PACKAGES

(71) Applicant: SAMSUNG ELECTRONICS CO., LTD., SUWON-SI (KR)

(72) Inventors: HYUNSOO CHUNG, Suwon-si (KR); KWANG-SOO KIM, Suwon-si (KR); SANG CHEON PARK, Suwon-si (KR)

(21) Appl. No.: 18/405,107

(22) Filed: Jan. 5, 2024

(30) Foreign Application Priority Data
Jul. 6, 2023 (KR) 10-2023-0087644

(51) Int. Cl. H01L 25/065; H01L 23/00; H01L 23/31; H01L 23/48; H10B 80/00

(52) U.S. Cl. CPC H01L 25/0657; H01L 23/3128; H01L 23/481; H01L 24/08; H10B 80/00; H01L 2224/08145

(57) ABSTRACT

A semiconductor stack structure includes: a plurality of semiconductor dies vertically stacked on each other; and one or more dummy dies positioned between the plurality of semiconductor dies, wherein each of the one or more dummy dies includes: a dummy die base; a first interconnection structure positioned on a first side of the dummy die base and including a plurality of first bonding pads, wherein the first bonding pads are positioned at substantially regular intervals; and a second interconnection structure positioned on a second side of the dummy die base and including a plurality of second bonding pads, wherein the second bonding pads are positioned at substantially regular intervals.

### CROSS-REFERENCE TO RELATED APPLICATION

This application claims priority under 35 U.S.C. § 119 to Korean Patent Application No. 10-2023-0087644, filed in the Korean Intellectual Property Office on Jul. 6, 2023, the disclosure of which is incorporated by reference herein in its entirety.

### TECHNICAL FIELD

The present inventive concept relates to a semiconductor package.

### DISCUSSION OF THE RELATED ART

Currently under development is a semiconductor package that is miniaturized, lightweight, and thin, while having high-speed performance, is multifunctional, and has a large-capacity, which is to meet a demand for miniaturization and light weight of electronic devices that incorporate the semiconductor package. Accordingly, a desire for packaging technology that can store more data and transmit data at a higher speed is increasing, and as an example of the packaging technology, a high-bandwidth memory (HBM) capable of achieving a high level of bandwidth by stacking more DRAMs on a substrate having a same area as each other has generally been used.

When hybrid bonding technology is applied to the stacking of DRAMs of such a high-bandwidth memory (HBM), surface topography of each DRAM stack is accumulated on an upper portion of the high-bandwidth memory (HBM), and as a result, stack voids may occur at interfaces between DRAM dies.

Thus, a new package technology capable of preventing stack voids from occurring in the high-bandwidth memory (HBM), to which such hybrid bonding technology is applied, has been under development.

### SUMMARY

According to an embodiment of the present inventive concept, a semiconductor stack structure includes: a plurality of semiconductor dies vertically stacked on each other; and one or more dummy dies positioned between the plurality of semiconductor dies, wherein each of the one or more dummy dies includes: a dummy die base; a first interconnection structure positioned on a first side of the dummy die base and including a plurality of first bonding pads, wherein the first bonding pads are positioned at substantially regular intervals; and a second interconnection structure positioned on a second side of the dummy die base and including a plurality of second bonding pads, wherein the second bonding pads are positioned at substantially regular intervals.

According to an embodiment of the present inventive concept, a semiconductor stack structure includes: a plurality of semiconductor dies vertically stacked; and one or more dummy dies positioned between the plurality of semiconductor dies, wherein each of the one or more dummy dies includes: a dummy die base; a first interconnection structure positioned on a first side of the dummy die base, wherein the first interconnection structure includes a plurality of first bonding pads positioned at substantially regular intervals and a first silicon insulating layer at least partially surrounding the first bonding pads; and a second interconnection structure positioned on a second side of the dummy die base, wherein the second connection structure includes a plurality of second bonding pads positioned at substantially regular intervals and a second silicon insulating layer at least partially surrounding the second bonding pads, wherein each of the semiconductor dies includes: a semiconductor die base; a third interconnection structure positioned on a first side of the semiconductor die base and positioned in a front side direction of the semiconductor die, wherein the third interconnection structure includes a plurality of third bonding pads and a third silicon insulating layer at least partially surrounding the third bonding pads; and a fourth interconnection structure positioned on a second of the semiconductor die base and positioned in a back side direction of the semiconductor die, wherein the fourth interconnection structure includes a plurality of fourth bonding pads and a fourth silicon insulating layer at least partially surrounding the fourth bonding pads.

According to an embodiment of the present inventive concept, a semiconductor package includes: an interposer; a plurality of semiconductor stack structures disposed on the interposer; a semiconductor structure disposed on the interposer; and a molding material positioned on the interposer and covering the semiconductor stack structures and the semiconductor structure, wherein each of the semiconductor stacked structures includes: a plurality of first semiconductor dies vertically stacked on each other; and one or more dummy dies positioned between the plurality of first semiconductor dies, wherein each of the one or more dummy dies includes: a dummy die base; a first interconnection structure positioned on a first side of the dummy die base and including a plurality of first bonding pads, wherein the first bonding pads are positioned at substantially regular intervals; and a second interconnection structure positioned on a second side of the dummy die base and including a plurality of second bonding pads, wherein the second bonding pads are positioned at substantially regular intervals.

### BRIEF DESCRIPTION OF THE DRAWINGS

FIG. 1 illustrates a cross-sectional view showing accumulated surface topography of a semiconductor stack when the semiconductor stack is formed using 12H-semiconductor dies in a high-bandwidth memory (HBM) including the semiconductor stack in which the 12H-semiconductor dies are bonded to each other and stacked by applying hybrid bonding technology.

FIG. 2 illustrates a graph showing deviation values of surface topography measured on semiconductor dies before performing a wafer thinning process and on 8H-semiconductor dies, 12H-semiconductor dies, and 16H-semiconductor dies after performing the wafer thinning process.

FIG. 3 illustrates a cross-sectional view showing a high-bandwidth memory (HBM) including a semiconductor stack in which stack voids are formed in a high-level stack of FIG. 1, and a graph showing deviation values of surface topography corresponding to each 12H-semiconductor die of the high-bandwidth memory (HBM) including the semiconductor stack in which the stack voids are formed in the high-level stack.

FIG. 4 illustrates a graph showing a measured value of a void ratio according to a number of stacked layers of a 12H-semiconductor die in a high-bandwidth memory (HBM).

FIG. 5 illustrates a cross-sectional view showing a high-bandwidth memory (HBM) with a dummy die interposed between stacked 12H-semiconductor dies according to an embodiment of the present inventive concept, and a graph showing deviation values of surface topography corresponding to each 12H-semiconductor die and dummy die in a high-bandwidth memory (HBM), in which a dummy die is interposed between the stacked 12H-semiconductor dies.

FIG. 6 illustrates a cross-sectional view showing cross-sections of a 12H-semiconductor die, an 8H-semiconductor die, a 16H-semiconductor die, and a dummy die according to an embodiment of the present inventive concept.

FIG. 7 illustrates a cross-sectional view showing a high-bandwidth memory (HBM) in which a dummy die is interposed between stacked 12H-semiconductor dies according to an embodiment of the present inventive concept.

FIG. 8 illustrates a cross-sectional view showing a high-bandwidth memory (HBM) in which a plurality of dummy dies are interposed between stacked 12H-semiconductor dies according to an embodiment of the present inventive concept.

FIG. 9 illustrates a cross-sectional view showing a high-bandwidth memory (HBM) in which 12H-semiconductor dies and dummy dies are alternately stacked on each other according to an embodiment of the present inventive concept.

FIG. 10 illustrates a cross-sectional view showing a cross-section of a 2.5D semiconductor package including a high-bandwidth memory (HBM) according to an embodiment of the present inventive concept.

FIG. 11 illustrates a cross-sectional view showing a cross-section of a 3D semiconductor package including a high-bandwidth memory (HBM) according to an embodiment of the present inventive concept.

### DETAILED DESCRIPTION OF EMBODIMENTS

Embodiments of the present inventive concept will be described more fully hereinafter with reference to the accompanying drawings. As those skilled in the art would realize, the described embodiments may be modified in various different ways, all without departing from the spirit and scope of the present inventive concept.

The drawings and description are to be regarded as illustrative in nature and not restrictive. Like reference numerals designate like elements throughout the specification and drawings, and thus, their descriptions may be omitted or briefly discussed.

In the drawings, various thicknesses, lengths, and angles are shown and while the arrangement shown does indeed represent an embodiment of the present inventive concept, it is to be understood that modifications of the various thicknesses, lengths, and angles may be possible within the spirit and scope of the present inventive concept and the present inventive concept is not necessarily limited to the particular thicknesses, lengths, and angles shown.

Throughout this specification and the claims that follow, when it is described that an element is “coupled/connected” to another element, the element may be “directly coupled/connected” to the other element or “indirectly coupled/connected” to the other element through a third element.

It will be understood that when an element such as a layer, film, region, or substrate is referred to as being “on” another element, it can be directly on the other element or intervening elements may also be present. In contrast, when an element is referred to as being “directly on” another element, there are no intervening elements present between the element and the other element. Further, in the specification, the word “on” or “above” means positioned on or below the object portion, and does not necessarily mean positioned on the upper side of the object portion based on a gravitational direction.

Further, throughout the specification, the phrase “in a plan view” means when an object portion is viewed from above unless indicated otherwise, and the phrase “in a cross-sectional view” means when a cross-section taken by vertically cutting an object portion is viewed from the side.

Hereinafter, a semiconductor package according to an embodiment of the present inventive concept will be described with reference to drawings.

A high-bandwidth memory (HBM) is a high-performance three-dimensional (3D) stacked dynamic random access memory RAM (DRAM). The high-bandwidth memory (HBM) may be manufactured by vertically stacking memory dies including DRAM circuits to form a single memory stack, forming thousands of fine holes vertically penetrating the stacked memory dies in the memory dies, and forming through silicon via (TSV) technology in which fine holes are electrically connected by filling them with a conductive material.

The high-bandwidth memory (HBM) may implement short latency and high bandwidth compared to conventional DRAM products together by having multiple memory channels through a memory stack in which memory dies are vertically stacked, and may reduce a total area occupied by individual DRAMs on a printed circuit board (PCB), which may provide high bandwidth compared to area and may reduce power consumption.

In addition, the high-bandwidth memory (HBM) has a problem in that it may be difficult to stack memory dies above a certain height due to structural limitations of a semiconductor package and difficulty of stacking technology, and a number of memory dies that can be included in each memory stack is limited.

In the high-bandwidth memory (HBM), 8H, 12H, and 16H semiconductor dies (memory dies) may be stacked in one memory stack. The 8H-semiconductor die refers to one memory die among eight memory dies in a case where the eight memory dies from a 1H layer to an 8H layer are stacked to form one memory stack. A vertical thickness of the 8H-semiconductor die may be about 55 μm. The 12H-semiconductor die refers to one memory die among 12 memory dies in a case where the 12 memory dies from a 1H layer to a 12H layer are stacked to form one memory stack. A vertical thickness of the 12H-semiconductor die may be about 38 μm. The 16H-semiconductor die refers to one memory die among 16 memory dies in a case where the 16 memory dies from a 1H layer to a 16H layer are stacked to form one memory stack. A vertical thickness of the 16H-semiconductor die may be about 27 μm. According to an embodiment of the present inventive concept, the high-bandwidth memory (HBM) in which 8H-semiconductor dies, 12H-semiconductor dies and 16H-semiconductor dies are stacked is disclosed, but the present inventive concept is not limited thereto, and configurations including other numbers of layers may be included within the scope of the present inventive concept.

In addition, the semiconductor dies of high-bandwidth memory (HBM) may be bonded by applying a hybrid bonding process. The hybrid bonding is to bond two devices by fusing same materials of the two devices using a bonding property of a same material. Herein, hybrid indicates that two different types of bonding are made, e.g., bonding two devices with a first type of metal-metal bonding and a second type of non-metal-non-metal bonding. If semiconductor dies are bonded through hybrid bonding as described above, a multi-level stack may be formed without using solder balls, and wire bonding may be performed with a very small bonding pitch.

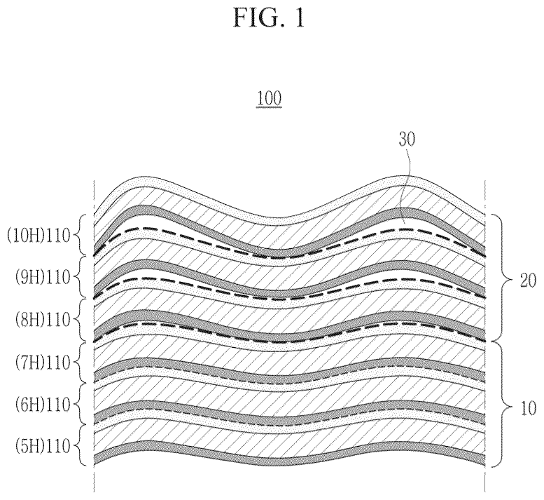

FIG. 1 illustrates a cross-sectional view showing accumulated surface topography of a semiconductor stack when the semiconductor stack is formed using 12H-semiconductor dies 110 in a high-bandwidth memory (HBM) 100 including the semiconductor stack in which the 12H-semiconductor dies 110 are directly bonded to each other and stacked by applying hybrid bonding technology. In FIG. 1, for convenience, six 12H-semiconductor dies 110 from a 5H layer to a 10H layer are illustrated, and the remaining six 12H-semiconductor dies 110 from a 1H layer to a 4H layer, a 11H layer, and a 12H layer are not illustrated.

Referring to FIG. 1, in a semiconductor stack formed by stacking twelve 12H-semiconductor dies 110 having a vertical thickness of about 38 μm from the 1H layer to the 12H layer, stack voids were not detected at an interface between the 12H-semiconductor dies 110 of a low-level stack 10 of the semiconductor stack, but it can be seen that a stack void 30 is detected at an interface between the 12H-semiconductor dies 110 of a high-level stack 20 of the semiconductor stack. The stack void 30 may be checked from an image inspected using scanning acoustic tomography (SAT) equipment.

The stack void 30 in the high-level stack 20 of the semiconductor stack may be caused by increasing accumulated surface topography of the high-bandwidth memory (HBM) 100 in which the 12H-semiconductor dies 110 are stacked, and the stack void 30 that is generated in this way may again cause a significant increase in the accumulated surface topography of the semiconductor stack. Due to this vicious cycle, the accumulated surface topography of the stacked semiconductor stacks greatly increases, and more stack voids 30 may be formed. An increase in the accumulated surface topography and the stack void 30 of the stacked semiconductor stack may degrade etch uniformity during a subsequent through-silicon via formation process, and may cause bonding failure during the hybrid bonding process, which may consequently lead to a large yield loss.

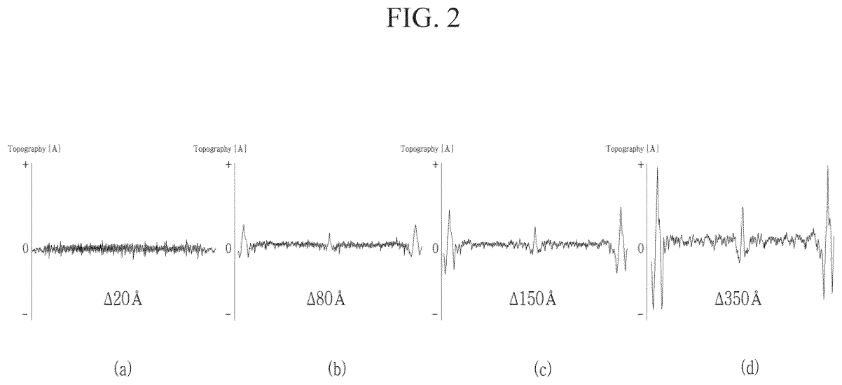

FIG. 2 illustrates a graph showing deviation values of surface topography measured on semiconductor dies before performing a wafer thinning process and on 8H-semiconductor dies, 12H-semiconductor dies, and 16H-semiconductor dies after performing the wafer thinning process.

Referring to FIG. 2, (a) a surface topography deviation of the semiconductor die before performing a wafer thin film process on the semiconductor die, (b) a surface topography deviation of the 8H-semiconductor die formed by performing the wafer thin film process on the semiconductor die, (c) a surface topography deviation of the 12H-semiconductor die formed by performing the wafer thin film process on the semiconductor die, and (d) a surface topography deviation of the 16H-semiconductor die formed by performing the wafer thin film process on the semiconductor die may be known.

In a process of forming a semiconductor stack by performing hybrid bonding, a process of thinning a wafer is performed to form through-silicon vias on a back side of a semiconductor die.

(a) The vertical thickness of the semiconductor die measured before performing a process of thinning a back wafer of the semiconductor die was about 775 μm, and a difference between a maximum value and a minimum value of the surface topography measurement was measured to be about 20 Å.

(b) A vertical thickness of the 8H-semiconductor die formed after performing the process of thinning the back wafer of the semiconductor die was about 55 μm, and the difference between the maximum value and the minimum value of the surface topography measurement was measured to be about 80 Å.

(c) A vertical thickness of the 12H-semiconductor die formed after performing the process of thinning the back wafer of the semiconductor die was about 38 μm, and the difference between the maximum and minimum values of the surface topography measurement was measured to be about 150 Å.

(d) A vertical thickness of the 16H-semiconductor die formed after performing the process of thinning the back wafer of the semiconductor die was about 27 μm, and the difference between the maximum and minimum values of the surface topography measurement was measured to be about 350 Å.

(a) The vertical thickness of the semiconductor die measured without thinning the back wafer of the semiconductor die is about 775 μm, and the deviation of the surface topography is about 20 Å. (d) The vertical thickness of the 16H-semiconductor die measured after performing the process of thinning the back wafer of the semiconductor die is about 27 μm, and the deviation of the surface topography is about 350 Å. Thus, in (d), it can be seen that the thickness is reduced by about 28 times compared to (a), while the deviation of the surface topography is increased by about 15 times. Accordingly, to include more semiconductor dies in high-bandwidth memory (HBM), as the thickness of semiconductor dies is made thinner, the variation in surface topography increases, and a possibility of forming the stack void 30 in the high-level stack 20 of the semiconductor stack increases.

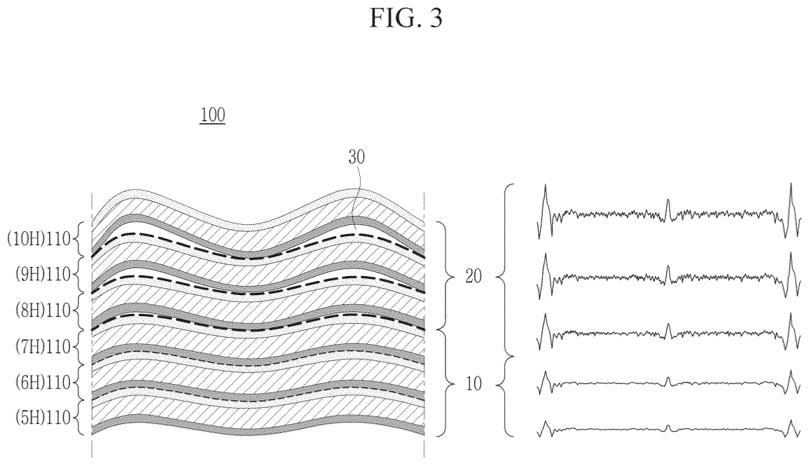

FIG. 3 illustrates a cross-sectional view showing the high-bandwidth memory (HBM) 100 including a semiconductor stack in which the stack void 30 is formed in the high-level stack 20 of FIG. 1, and a graph showing deviation values of surface topography corresponding to each 12H-semiconductor die 110 of the high-bandwidth memory (HBM) 100 including the semiconductor stack in which the stack void 30 is formed in the high-level stack.

Referring to FIG. 3, a high-bandwidth memory (HBM) 100 may include the semiconductor stack in which twelve 12H-semiconductor dies 110 having a vertical thickness of about 38 μm are stacked from a 1H layer to a 12H layer. According to the surface topography deviation graph corresponding to the 12H-semiconductor die 110 of the 5H layer to the 12H-semiconductor die 110 of the 10H layer, it can be seen that the deviation of the surface topography increases cumulatively and the stack void 30 is better formed from the 12H-semiconductor die 110 of the 5H layer to the 12H-semiconductor die 110 of the 10H layer.

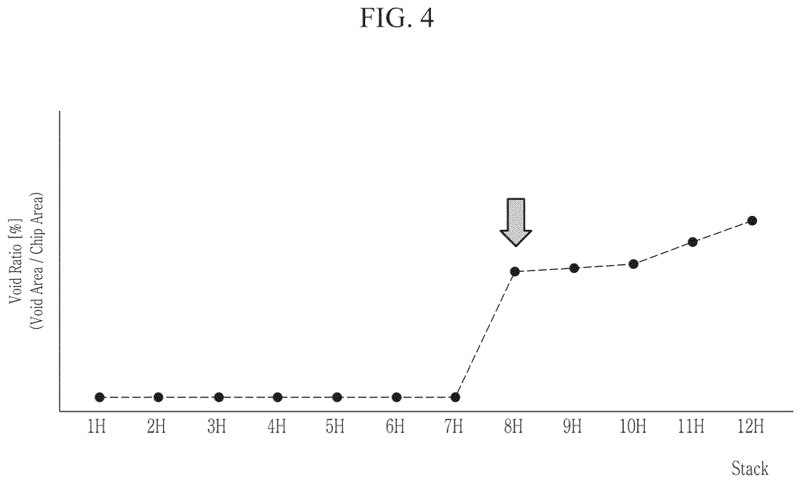

FIG. 4 illustrates a graph showing a measured value of a void ratio according to a number of stacked layers of the 12H-semiconductor die 110 in a high-bandwidth memory (HBM).

Referring to FIG. 4, an X-axis represents the number of layers in which 12H-semiconductor die 110 is stacked, and a Y-axis represents a ratio of an area of stacked voids 30 to an area of 12H-semiconductor die 110. Stack voids are not formed when the 12H-semiconductor die 110 is stacked from the 1H layer to the 7H layer. The stack voids 30 start to form in the 8H layer in which one more 12H-semiconductor die 110 is stacked, and as the 12H-semiconductor die 110 is stacked from the 9H layer to the 12H layer, it can be seen that the stack voids 30 are further increased.

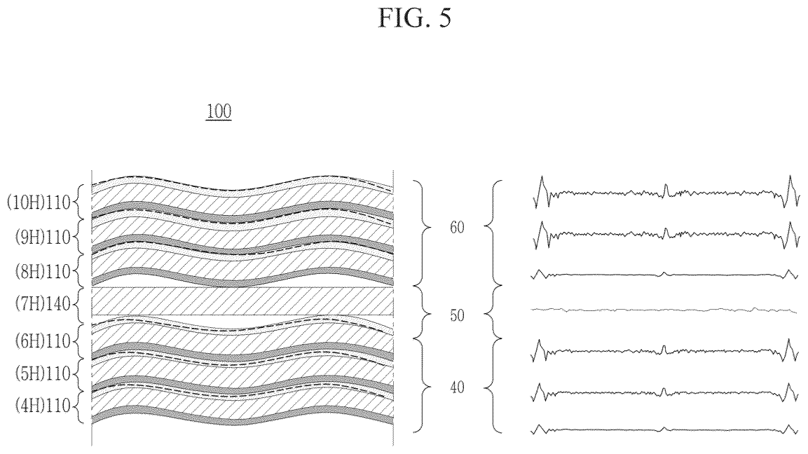

FIG. 5 illustrates a cross-sectional view showing the high-bandwidth memory (HBM) 100 with a dummy die interposed between the stacked 12H-semiconductor dies 110 according to an embodiment of the present invention, and a graph showing deviation values of surface topography corresponding to each 12H-semiconductor die 110 and dummy die 140 in a high-bandwidth memory (HBM) in which the dummy die 140 is interposed between the stacked 12H-semiconductor dies 110.

Referring to FIG. 5, the high-bandwidth memory (HBM) 100 may include six 12H-semiconductor dies 110 having a vertical thickness of about 38 μm from the 1H layer to the 6H layer, may include the dummy die 140 having a vertical thickness of less than about 38 μm in the 7H layer, and may again include five 12H-semiconductor dies 110 with a vertical thickness of about 38 μm from the layer 8H to the layer 12H. According to the surface topography deviation graph corresponding to the semiconductor stack, it can be seen that, in the low-level stack 40 of the 12H-semiconductor die 110 from a 4H layer to a 6H layer, a deviation of the surface topography accumulates and gradually increases. However, in the 7H layer 50, the dummy die 140, which has a vertical thickness smaller than that of the 12H-semiconductor die 110, is interposed between the low-level stack 40 and the high-level stacks 60 to mitigate the accumulation of deviations in surface topography, and in subsequent high-level stacks 60 of 8H, 9H, and 10H layers of 12H-semiconductor dies 110, an increase in variation in surface topography due to accumulation may be mitigated.

As such, in the high-bandwidth memory (HBM) 100 in which the 12H-semiconductor dies 110 are stacked, if the dummy die 140 is included between the 12H-semiconductor dies 110, an increase in surface topography due to accumulation may be alleviated, and formation of the stack voids 30 caused by the increase in surface topography in the 12H-semiconductor stack may be prevented.

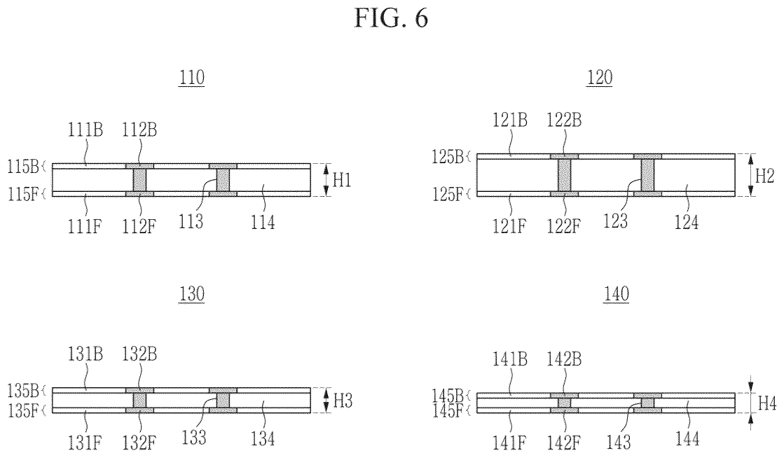

FIG. 6 illustrates a cross-sectional view showing cross-sections of the 12H-semiconductor die 110, an 8H-semiconductor die 120, a 16H-semiconductor die 130, and the dummy die 140 according to an embodiment of the present invention.

Referring to FIG. 6, the 12H-semiconductor die 110 may include a front interconnection structure 115F, a back interconnection structure 115B, a through silicon via 113, and a semiconductor die base 114. In an embodiment of the present inventive concept, a vertical thickness H1 of the 12H-semiconductor dies 110 may be about 38 μm or less.

The front interconnection structure 115F may be positioned at a first side of the semiconductor die base 114. The front interconnection structure 115F may be positioned at a front side of the 12H-semiconductor die 110. The front interconnection structure 115F may each include a front silicon insulating layer 111F and front bonding pads 112F. The back interconnection structure 115B may be disposed at a second side, which is an opposite side of a first side of the semiconductor die base 114. The back interconnection structure 115B may be positioned at a back side of the 12H-semiconductor die 110. The back interconnection structure 115B may include a back silicon insulating layer 111B and back bonding pads 112B.

The front silicon insulating layer 111F may at least partially surround and insulate the front bonding pads 112F. The back silicon insulating layer 111B may at least partially surround and insulate the back bonding pads 112B. A first side of each of the front bonding pad 112F and the back bonding pad 112B may be electrically connected to the through silicon via 113, and a second side, which is opposite side of the first side, of each of the front bonding pad 112F and the back bonding pad 112B may be respectively electrically connected to bonding pads of the other semiconductor dies by being bonded to the bonding pads of the other semiconductor dies by hybrid bonding.

The through silicon vias 113 may be formed to extend the through semiconductor die base 114. The through silicon vias 113 may be positioned between the front bonding pads 112F and the back bonding pads 112B. A first end of the through silicon via 113 may be electrically connected to the front bonding pad 112F, and a second end of the through silicon via 113 may be electrically connected to the back bonding pad 112B. The semiconductor die base 114 may be interposed between the front interconnection structure 115F and the back interconnection structure 115B. The semiconductor die base 114 may include, for example, a DRAM circuit.

The 8H-semiconductor die 120 may include a front interconnection structure 125F, a back interconnection structure 125B, a through silicon via 123, and a semiconductor die base 124. In an embodiment of the present invention, a vertical thickness H2 of the 8H-semiconductor dies 120 may be about 55 μm or less.

The front interconnection structure 125F may be positioned at a first side of the semiconductor die base 124. The front interconnection structure 125F may be positioned at a front side of the 8H-semiconductor die 120. The front interconnection structure 125F may include a front silicon insulating layer 121F and front bonding pads 122F. The back interconnection structure 125B may be disposed at a second side, which is an opposite side of a first side of the semiconductor die base 124. The back interconnection structure 125B may be positioned at a back side of the 8H-semiconductor die 120. The back interconnection structure 125B may include a back silicon insulating layer 121B and back bonding pads 122B.

The front silicon insulating layer 121F may at least partially surround and insulate the front bonding pads 122F. The back silicon insulating layer 121B may at least partially surround and insulate the back bonding pads 122B. A first side of each of the front bonding pad 122F and the back bonding pad 122B may be electrically connected to the through silicon via 123, and a second side, which is opposite side of the first side, of each of the front bonding pad 122F and the back bonding pad 122B may be respectively electrically connected to bonding pads of the other semiconductor dies by being bonded to the bonding pads of the other semiconductor dies by hybrid bonding.

The through silicon vias 123 may be formed to extend the through semiconductor die base 124. The through silicon vias 123 may be positioned between the front bonding pads 122F and the back bonding pads 122B. A first end of the through silicon via 123 may be electrically connected to the front bonding pad 122F, and a second end of the through silicon via 123 may be electrically connected to the back bonding pad 122B. The semiconductor die base 124 may be interposed between the front interconnection structure 125F and the back interconnection structure 125B. The semiconductor die base 124 may include, for example, a DRAM circuit.

The 16H-semiconductor die 130 may include a front interconnection structure 135F, a back interconnection structure 135B, a through silicon via 133, and a semiconductor die base 134. In an embodiment of the present invention, a vertical thickness H3 of the 16H-semiconductor dies 130 may be about 27 μm or less.

The front interconnection structure 135F may be positioned at a first side of the semiconductor die base 134. The front interconnection structure 135F may be positioned at a front side of the 16H-semiconductor die 130. The front interconnection structure 135F may each include a front silicon insulating layer 131F and front bonding pads 132F. The back interconnection structure 135B may be disposed at a second side, which is an opposite side of a first side of the semiconductor die base 134. The back interconnection structure 135B may be positioned at a back side of the 16H-semiconductor die 130. The back interconnection structure 135B may include a back silicon insulating layer 131B and back bonding pads 132B.

The front silicon insulating layer 131F may at least partially surround and insulate the front bonding pads 132F. The back silicon insulating layer 131B may at least partially surround and insulate the back bonding pads 132B. A first side of each of the front bonding pad 132F and the back bonding pad 132B may be electrically connected to the through silicon via 133, and a second side, which is opposite side of the first side, of each of the front bonding pad 132F and the back bonding pad 132B may be respectively electrically connected to bonding pads of the other semiconductor dies by being bonded to the bonding pads of the other semiconductor dies by hybrid bonding.

The through silicon vias 133 may be formed to extend the through semiconductor die base 134. The through silicon vias 133 may be positioned between the front bonding pads 132F and the back bonding pads 132B. A first end of the through silicon via 133 may be electrically connected to the front bonding pad 132F, and a second end of the through silicon via 133 may be electrically connected to the back bonding pad 132B. The semiconductor die base 134 may be interposed between the front interconnection structure 135F and the back interconnection structure 135B. The semiconductor die base 134 may include, for example, a DRAM circuit.

The dummy die 140 may include a first interconnection structure 145F, a second interconnection structure 145B, through-silicon vias 143, and a dummy die base 144. The dummy die 140 is configured to mitigate the accumulation of surface topography, and thus, a difference between a maximum thickness and a minimum thickness of the dummy die 140 in the vertical direction may be about 50 Å or less. In an embodiment of the present inventive concept, a vertical thickness H4 of the dummy die 140 that is interposed between the semiconductor stacks in which the 12H-semiconductor dies 110 are stacked may be about 38 μm or less. In an embodiment of the present inventive concept, a vertical thickness of the dummy die 140 that is interposed between the semiconductor stacks in which the 8H-semiconductor dies 120 are stacked may be about 55 μm or less. In an embodiment of the present inventive concept, a vertical thickness of the dummy die 140 interposed between the semiconductor stacks in which the 16H-semiconductor dies 130 are stacked may be about 27 μm or less.

The first interconnection structure 145F may be positioned on a first side of the dummy die base 144. The first interconnection structure 145F may include a first silicon insulating layer 141F and first bonding pads 142F. The second interconnection structure 145B may be positioned on second side opposite to the first side of the dummy die base 144. The second interconnection structure 145B may include a second silicon insulating layer 141B and second bonding pads 142B. In an embodiment of the present inventive concept, to facilitate hybrid bonding, surface roughness of the first interconnection structure 145F and the second interconnection structure 145B may be about 10 Å or less.

The first silicon insulating layer 141F may at least partially surround and insulate the first bonding pads 142F. The second silicon insulation layer 141B may at least partially surround and insulate the second bonding pads 142B. A first side of each of the first bonding pad 142F and the second bonding pad 142B may be electrically connected to the through silicon via 143, and a second side, which is opposite sides of the first side, of each of the first bonding pad 142F and the second bonding pad 142B may be respectively electrically connected to bonding pads of the other semiconductor dies by being bonded to the bonding pads of the other semiconductor dies by hybrid bonding. The first bonding pads 142F and the second bonding pads 142B of the dummy die 140 may be respectively positioned to have a same area density with respect to surfaces on which the first bonding pads 142F and the second bonding pads 142B are positioned. The first bonding pads 142F and the second bonding pads 142B of the dummy die 140 may be positioned at substantially regular intervals. In the dummy die 140, each first bonding pad among the first bonding pads 142F and each second bonding pad among the second bonding pads 142B may be positioned to have a constant metal ratio.

The through silicon vias 143 may be formed to extend the through dummy die base 144. The through silicon vias 143 may be positioned between the first bonding pads 142F and the second bonding pads 142B. A first end of the through silicon via 143 may be electrically connected to the first bonding pad 142F, and a second end of the through silicon via 143 may be electrically connected to the second bonding pad 142B. The dummy die base 144 may be interposed between the first interconnection structure 145F and the second interconnection structure 145B. The dummy die base 144 of the dummy die 140 may be a wafer die on which circuits are not formed.

In an embodiment of the present inventive concept, the front silicon insulating layers 111F, 121F, and 131F and the first silicon insulating layer 141F may be deposited through chemical vapor deposition (CVD), atomic layer deposition (ALD), plasma-enhanced chemical vapor deposition (PECVD), or other methods. In an embodiment of the present inventive concept, the back silicon insulating layers 111B, 121B, and 131B and the second silicon insulating layer 141B may be deposited through chemical vapor deposition (CVD), atomic layer deposition (ALD), plasma enhanced chemical vapor deposition (PECVD), or other methods after performing a thin film process on the back side of the wafer.

The front silicon insulating layers 111F, 121F, and 131F, the first silicon insulating layer 141F, and the back silicon insulating layers 111B, 121B, and 131B, and the second silicon insulating layer 141B may include a silicon oxide. In an embodiment of the present inventive concept, the front silicon insulating layers 111F, 121F, and 131F, the first silicon insulating layer 141F, the back silicon insulating layers 111B, 121B, and 131B, and the second silicon insulating layer 141B may include SiO₂. In an embodiment of the present inventive concept, the front silicon insulating layers 111F, 121F, and 131F, the first silicon insulating layer 141F, and the back silicon insulating layers 111B, 121B, and 131B, and the second silicon insulating layer 141B may include a silicon nitride, a silicon oxynitride or other suitable dielectric material.

In an embodiment of the present inventive concept, the front bonding pads 112F, 122F, and 132F and the first bonding pad 142F may be formed by sputtering. In an embodiment of the present inventive concept, the front bonding pads 112F, 122F, and 132F and the first bonding pad 142F may be formed by electroplating. For example, the front bonding pads 112F, 122F, and 132F and the first bonding pad 142F may be formed by first forming a seed metal layer and growing a metal film by electrolytic plating from the seed metal layer. In an embodiment of the present inventive concept, after the front bonding pads 112F, 122F, and 132F and the first bonding pad 142F are formed, an annealing process may be performed. The back bonding pads 112B, 122B, and 132B and the second bonding pad 142B may be formed by, for example, performing a metal filling process through hard mask deposition, photoresist deposition, photomask deposition, exposure, development, and etching after performing a thin film process on a back side of the wafer.

For a metal filling process for forming the back bonding pads 112B, 122B, and 132B and the second bonding pad 142B, a same process as a metal filling process (e.g., sputtering, electroplating, or annealing) for forming the front bonding pads 112F, 122F, and 132F and the first bonding pad 142F may be performed. In an embodiment of the present inventive concept, the front bonding pads 112F, 122F, and 132F, the first bonding pad 142F, the back bonding pads 112B, 122B, and 132B, and the second bonding pad 142B may include copper. In an embodiment of the present inventive concept, the front bonding pads 112F, 122F, and 132F, the first bonding pad 142F, the back bonding pads 112B, 122B, and 132B, and the second bonding pad 142B may be formed of a metallic material capable of applying hybrid bonding.

In an embodiment of the present inventive concept, via holes of the through-silicon vias 113, 123, 133, and 143 may be formed by deep etching. In an embodiment of the present inventive concept, the via holes of the through silicon vias 113, 123, 133 and 143 may be formed by a laser. In an embodiment of the present inventive concept, via holes of the through silicon vias 113, 123, 133 and 143 may be filled with copper by electrolytic plating. In an embodiment of the present inventive concept, the through silicon vias 113, 123, 133, and 143 may include at least one of tungsten, aluminum, copper, or an alloy thereof.

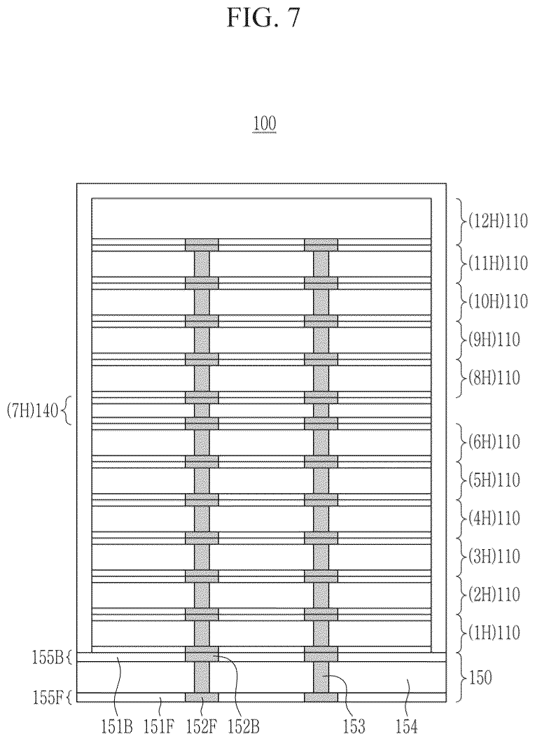

FIG. 7 illustrates a cross-sectional view showing a high-bandwidth memory (HBM) 100 in which the dummy die 140 is interposed between stacked 12H-semiconductor dies 110 according to an embodiment of the present inventive concept.

Referring to FIG. 7, the high-bandwidth memory (HBM) 100 may include the 12H-semiconductor dies 110, the dummy die 140 that is interposed between the 12H-semiconductor dies 110, and a buffer die 150. For example, the high-bandwidth memory (HBM) 100 may be formed by stacking 12H-semiconductor dies 110 from the 1H layer to the 6H layer, stacking the dummy die 140 on the 7H layer, and stacking 12H-semiconductor dies 110 again from the 8H layer to the 12H layer. As described in FIG. 4, if the 12H-semiconductor die 110 is stacked from the 1H layer to the 7H layer, the stack void 30 may occur at a boundary between the 12H-semiconductor die 110 in the 8H layer and the 12H-semiconductor die 110 in the 7H layer. Accordingly, if accumulation of deviations in the surface topography is alleviated by stacking 12H-semiconductor dies 110 having a vertical thickness of about 38 μm from the 1H layer to the 6H layer, and stacking the dummy die 140 on the 7H layer, and the 12H-semiconductor die 110 having a vertical thickness of about 38 μm is stacked again from the subsequent 8H layer to the 12H layer, it is possible to mitigate an increase in variation of surface topography due to accumulation.

In an embodiment of the present inventive concept, the high-bandwidth memory (HBM) 100 may be formed by stacking 12H-semiconductor dies 110 from the 1H layer to the 4H layer, stacking the dummy die 140 on the 5H layer, and stacking 12H-semiconductor dies 110 again from the 6H layer to the 12H layer.

If the 12H-semiconductor die 110 is stacked from the 5H layer to the 12H layer, the stack void 30 may occur at a boundary between the 12H-semiconductor die 110 in the 11H layer and the 12H-semiconductor die 110 in the 12H layer. Accordingly, if accumulation of deviations in the surface topography is alleviated by stacking 12H-semiconductor dies 110 having a vertical thickness of about 38 μm from the 1H layer to the 4H layer, and by stacking the dummy die 140 on the 5H layer, and the 12H-semiconductor die 110 having a vertical thickness of about 38 μm is stacked again from the subsequent 6H layer to the 12H layer, to form the high-bandwidth memory (HBM) 100, it is possible to mitigate an increase in variation of surface topography due to accumulation.

The high-bandwidth memory (HBM) 100 may include the buffer die 150 at a lowermost portion of the high-bandwidth memory (HBM) 100. The buffer die 150 may be positioned at a lowermost portion of the high-bandwidth memory (HBM) 100, and may be positioned between the 12H-semiconductor die 110 of the 1H and an external device. When exchanging data between devices with different data processing speeds, processing units, and usage times, data loss may occur due to differences in data processing speeds, processing units, and usage times between devices. To prevent this loss, the buffer die 150 may be positioned between the 12H-semiconductor die 110 of the 1H layer and an external device, and information when data is exchanged between a stack of 12H-semiconductor dies 110 and an external device may be temporarily stored in the buffer die 150. When transmitting data to the stack of 12H-semiconductor dies 110 or receiving data from the stack of 12H-semiconductor dies 110, the buffer die 150 may sequentially pass data after matching an order of the data.

The buffer die 150 may include a front interconnection structure 155F, a back interconnection structure 155B, a through silicon via 153, and a buffer die base 154.

The front interconnection structure 155F may be positioned at a first side of the buffer die base 154. The front interconnection structure 155F may be positioned at a front side of the buffer die 150. The front interconnection structure 155F may each include a front silicon insulating layer 151F and front bonding pads 152F. The back interconnection structure 155B may be disposed at a second side, which is an opposite side of a first side of the buffer die base 154. The back interconnection structure 155B may be positioned at a back side of the buffer die 150. The back interconnection structure 155B may include a back silicon insulating layer 151B and back bonding pads 152B.

The front silicon insulating layer 151F may at least partially surround and insulate the front bonding pads 152F. The back silicon insulating layer 151B may at least partially surround and insulate the back bonding pads 152B. A first side of each of the front bonding pad 152F and the back bonding pad 152B may be electrically connected to the through silicon via 153, and a second side, which is opposite sides of the first side, each of the front bonding pad 152F and the back bonding pad 152B may be bonded to a bonding pad of the 12H-semiconductor die 110 of the 1H layer or a bonding pad of an external device by hybrid bonding, to be electrically connected to a bonding pad of the 12H-semiconductor die 110 of the 1H layer or to a bonding pad of the external device.

The through silicon vias 153 may be formed to extend the through buffer die base 154. The through silicon vias 153 may be positioned between the front bonding pads 152F and the back bonding pads 152B. A first end of the through silicon via 153 may be electrically connected to the front bonding pad 152F, and a second end of the through silicon via 153 may be electrically connected to the back bonding pad 152B. The buffer die base 154 may be interposed between the front interconnection structure 155F and the back interconnection structure 155B. The buffer die base 154 may include a buffer circuit.

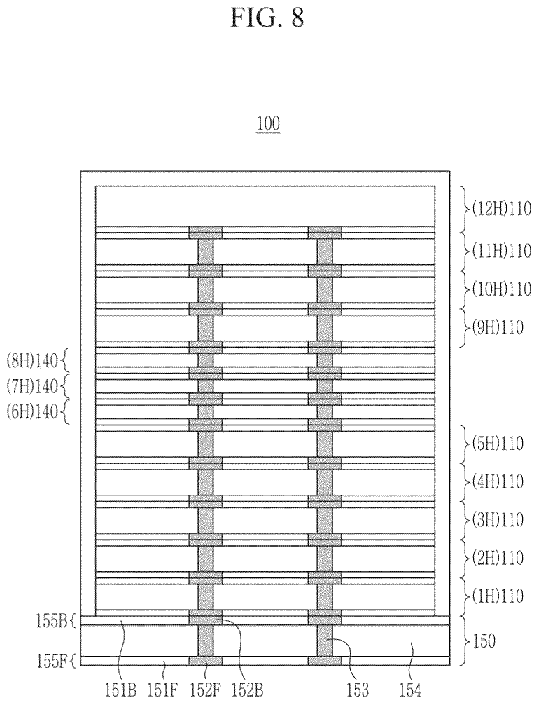

FIG. 8 illustrates a cross-sectional view showing the high-bandwidth memory (HBM) 100 in which a plurality of dummy dies 140 are interposed between stacked 12H-semiconductor dies 110 according to an embodiment.

Referring to FIG. 8, the high-bandwidth memory (HBM) 100 may include the 12H-semiconductor dies 110, the dummy dies 140 disposed between the 12H-semiconductor dies 110, and a buffer die 150. For example, 12H-semiconductor dies 110 may be stacked from the 1H layer to the 5H layer. For example, the dummy dies 140 may be stacked from the 6H layer to the 8H layer, and 12H-semiconductor dies 110 may be stacked again from the 9H layer to the 12H layer.

According to the embodiment of FIG. 8, if the high-bandwidth memory (HBM) 100 is formed by including the dummy dies 140 having a vertical thickness smaller than about 38 μm between 12H-semiconductor dies 110 having a vertical thickness of about 38 um, an increase in the variation of the surface topography due to accumulation may be more greatly alleviated than in the embodiment of FIG. 7.

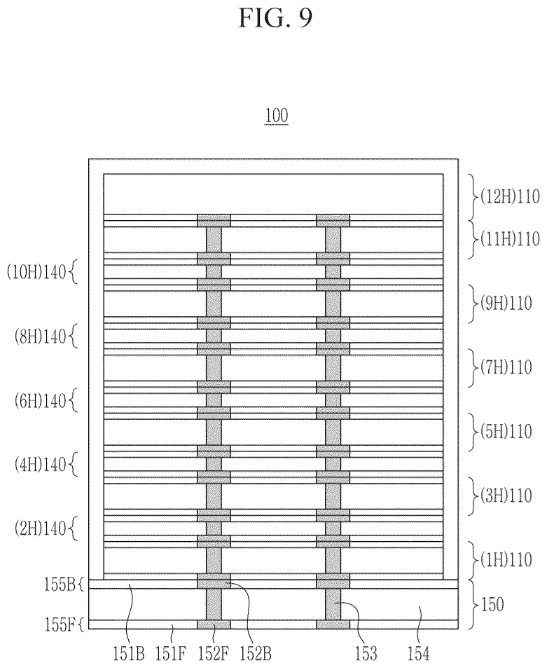

FIG. 9 illustrates a cross-sectional view showing the high-bandwidth memory (HBM) 100 in which the 12H-semiconductor dies 110 and the dummy dies 140 are alternately stacked according to an embodiment of the present inventive concept.

Referring to FIG. 9, the high-bandwidth memory (HBM) 100 may include the 12H-semiconductor dies 110, the dummy die 140 disposed between adjacent 12H-semiconductor dies 110, and the buffer die 150. For example, the high-bandwidth memory (HBM) 100 may be formed by stacking 12H-semiconductor dies 110 on the 1H, 3H, 5H, 7H, 9H, 11H, and 12H layers, and the dummy dies 140 on the 2H, 4H, 6H, 8H, and 10H layers.

According to the embodiment of FIG. 9, if the high-bandwidth memory (HBM) 100 is formed by alternately stacking 12H-semiconductor dies 110 and dummy dies 140 having a vertical thickness of about 38 μm, an increase in surface topography deviation due to accumulation may be more greatly alleviated than in the embodiment of FIG. 8.

A manufacturing method of a high-bandwidth memory (HBM) 100 including 12H-semiconductor dies 110 will be as follows. For reference, for a manufacturing method of a high-bandwidth memory (HBM) 100 including 8H-semiconductor dies 120 and 16H-semiconductor dies 130, the manufacturing method of the high-bandwidth memory (HBM) 100 including the 12H-semiconductor dies 110 may be applied in a same manner.

First, before performing a wafer thin film process, a front side of the first 12H-semiconductor die 110 and a front side of the second 12H-semiconductor die 110 are bonded by hybrid bonding.

The front bonding pads 112F of the first 12H-semiconductor die 110 may be bonded with the front bonding pads 112F of the second 12H-semiconductor die 110 through metal-metal hybrid bonding. Metal bonding is performed at an interface between the front surface bonding pads 112F of the first 12H-semiconductor die 110 and the front surface bonding pads 112F of the second 12H-semiconductor die 110 by metal-metal hybrid bonding. The front bonding pads 112F of the first 12H-semiconductor die 110 and the front bonding pads 112F of the second 12H-semiconductor die 110 are formed of a same material, and after hybrid bonding, the interface between the front bonding pads 112F of the first 12H-semiconductor die 110 and the front bonding pads 112F of the second 12H-semiconductor die 110 may disappear. The first 12H-semiconductor die 110 and the second 12H-semiconductor die 110 may be electrically connected to each other through the front bonding pads 112F of the first 12H-semiconductor die 110 and the front bonding pads 112F of the second 12H-semiconductor die 110.

The front silicon insulating layer 111F of the first 12H-semiconductor die 110 may be bonded to the front silicon insulating layer 111F of the second 12H-semiconductor die 110 by non-metal-non-metal hybrid bonding. Covalent bonding is performed at an interface between the front silicon insulating layer 111F of the first 12H-semiconductor die 110 and the front silicon insulating layer 111F of the second 12H-semiconductor die 110 by non-metal-non-metal hybrid bonding. The front silicon insulating layer 111F of the first 12H-semiconductor die 110 and the front silicon insulating layer 111F of the second 12H-semiconductor die 110 are formed of a same material as each other, and after hybrid bonding, the interface between the front silicon insulating layer 111F of the first 12H-semiconductor die 110 and the front silicon insulating layer 111F of the second 12H-semiconductor die 110 may disappear.

Then, a back wafer of the second 12H-semiconductor dies 110 is thinned by a thin film process. Thereafter, through holes are formed on a back surface of the second 12H-semiconductor dies 110 by using a laser or performing deep etching, and a through silicon vias 113 are formed by filling the through holes with a metal (e.g., copper). Next, the back bonding pads 112B and the back silicon insulating layers 111B are formed in a back side of the second 12H-semiconductor dies 110. Thereafter, the back sides of the second 12H-semiconductor dies 110 and the front sides of the third 12H-semiconductor dies 110 are bonded to each other by hybrid bonding. A same process may also be applied to the dummy die 140, and by repeating this process, a semiconductor stack including the 12H-semiconductor dies 110 and one or more dummy dies 140 may be stacked from the 1H layer to the 12H layer.

The high-bandwidth memory (HBM) 100 may include 12H-semiconductor dies of the 12H layer thicker than 12H-semiconductor dies of the 1H to 11H layers at an uppermost level. According to an embodiment of the present inventive concept, a vertical height of the high-bandwidth memory (HBM) 100, which may be reduced by including the dummy die 140 having a vertical thickness less than that of the 12H-semiconductor die 110 that is between 12H-semiconductor dies 110 having a vertical thickness of about 38 μm, may be adjusted by increasing the vertical thickness of the 12H-semiconductor die of the 12H layer.

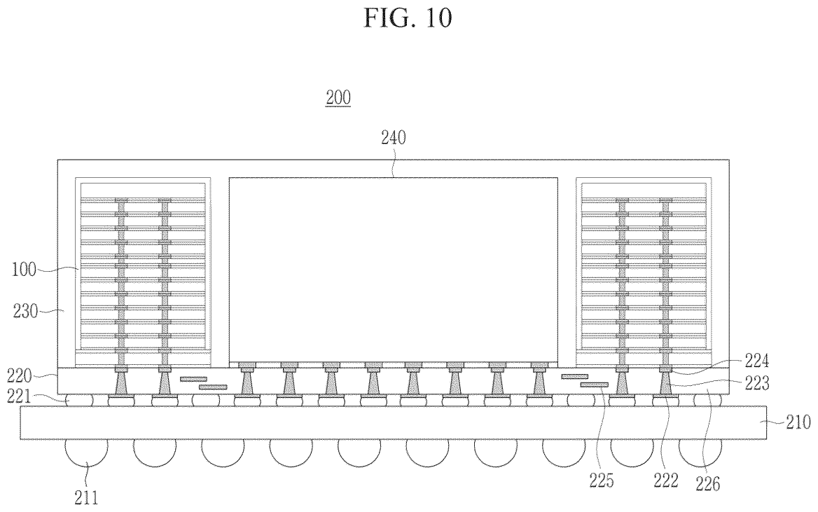

FIG. 10 illustrates a cross-sectional view showing a cross-section of a 2.5D semiconductor package 200 including a high-bandwidth memory (HBM) 100 according to an embodiment of the present inventive concept.

The 2.5D semiconductor package 200 may include a printed circuit board (PCB) 210, a silicon interposer 220, a high-bandwidth memory (HBM) 100, a logic circuit (e.g., a semiconductor structure) 240, and a molding material 230.

The printed circuit board (PCB) 210 may be electrically coupled to an external device through an external connection member 211. In an embodiment of the present inventive concept, the external connection member 211 may include a solder ball. In an embodiment of the present inventive concept, the external connection member 211 may include at least one of tin (Sn) and/or lead (Pb).

The silicon interposer 220 may include metal vias 223, bonding pads 222 and 224, redistribution lines 225, and an interposer base 226. The metal vias 223 and the redistribution lines 225 may be positioned between the bonding pads 222 and 224 and electrically connected to the bonding pads 222 and 224. The bonding pads 222 may be positioned between the connection member 221 and the metal via 223 and electrically connect the metal via 223 to the connection member 221. The bonding pads 224 are disposed between the high-bandwidth memory (HBM) 100 and the metal via 223, and between the logic circuit 240 and the metal via 223, and the high-bandwidth memory (HBM) 100 and the logic circuit 240 may be electrically connected to the metal via 223. In an embodiment of the present inventive concept, the interposer base 226 may be formed of silicon.

The connection member 221 may be positioned between the bonding pad 222 of the silicon interposer 220 and the printed circuit board (PCB) 210, and may electrically connect the silicon interposer 220 to the printed circuit board (PCB) 210. In an embodiment of the present inventive concept, the connection member 221 may include a solder ball. In an embodiment of the present inventive concept, the connection member 221 may include at least one of tin (Sn) and/or lead (Pb). In an embodiment of the present inventive concept, the connection member 221 may include at least one of tin (Sn), bismuth (Bi), silver (Ag), copper (CU), or an alloy thereof.

The high-bandwidth memory (HBM) 100 may include 12H-semiconductor dies 110 and one or more dummy dies 140 disposed between the 12H-semiconductor dies 110. In addition, the high-bandwidth memory (HBM) 100 may include 8H-semiconductor dies 120 and one or more dummy dies 140 disposed between the 8H-semiconductor dies 120. In addition, the high-bandwidth memory (HBM) 100 may include 16H-semiconductor dies 130 and one or more dummy dies 140 disposed between the 16H-semiconductor dies 130.

The logic circuit 240 may be positioned side-by-side with the high-bandwidth memories (HBM) 100 and may be positioned between the high-bandwidth memories (HBM) 100. In an embodiment of the present inventive concept, the logic circuit 240 may include a central processing unit (CPU) or a graphic processing unit (GPU).

The molding material 230 may mold high bandwidth memories (HBM) 100 and the logic circuit 240 on the silicon interposer 220. For example, the molding material 230 may be disposed on the high bandwidth memories (HBM) 100 and the logic circuit 240. In an embodiment of the present inventive concept, the molding material 230 may include an epoxy molding compound (EMC).

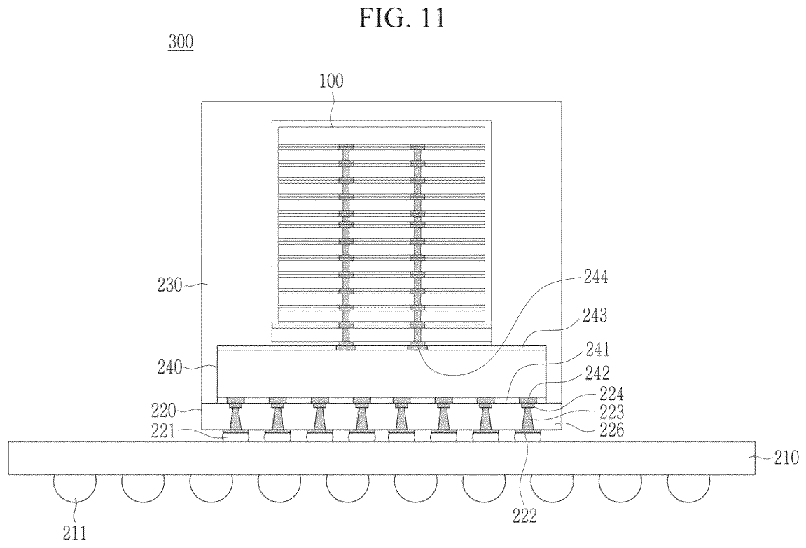

FIG. 11 illustrates a cross-sectional view showing a cross-section of a 3D semiconductor package 300 including a high-bandwidth memory (HBM) according to an embodiment. of the present inventive concept

The 3D semiconductor package 300 of FIG. 11 may include a printed circuit board (PCB) 210, a silicon interposer 220, a high-bandwidth memory (HBM) 100, a logic circuit (semiconductor structure) 240, a molding material 230, an external connection member 211, and a connection member 221, and the silicon interposer 220 may include metal vias 223, bonding pads 222 and 224, and an interposer base 226, but characteristics of the components of the 2.5D semiconductor package 200 of FIG. 10 may be identically applied to the corresponding components.

Referring to FIG. 11, the semiconductor package 300 may include a logic circuit 240, which is mounted on the silicon interposer 220, and a high-bandwidth memory (HBM) 100, which is mounted on the logic circuit 240. Unlike the logic circuit 240 disposed side-by-side with the high-bandwidth memories (HBM) 100 on the silicon interposer 220 in the embodiment of FIG. 10, in FIG. 11, the silicon interposer 220, the logic circuit 240, and the high-bandwidth memory (HBM) 100 may be vertically stacked on each other. In this case, the silicon interposer 220, the logic circuit 240, and the high-bandwidth memory (HBM) 100 may be connected to each other by performing hybrid bonding and may be electrically connected to each other. A silicon insulating layer 241 of the logic circuit 240 may be bonded to the interposer base 226 of the silicon interposer 220 by performing hybrid bonding, and may be electrically coupled to each other. Bonding pads 242 of the logic circuit 240 may be bonded to the bonding pads 224 of the silicon interposer 220 by performing hybrid bonding, and may be electrically connected to each other. A silicon insulating layer 243 of the logic circuit 240 may be bonded to a front silicon insulating layer 151F of the buffer die 150 of the high-bandwidth memory (HBM) 100 by performing hybrid bonding, and may be electrically connected to each other. The bonding pads 244 of the logic circuit 240 may be connected to the front bonding pads 152F of the buffer die 150 of the high-bandwidth memory (HBM; 100) through hybrid bonding, and may be electrically coupled to each other.

According to embodiments of the present inventive concept, a 12H-semiconductor stack and an 8H-semiconductor stack have been described, but the present inventive concept is not limited thereto, and other configurations such as a 16H-semiconductor stack may be included within the scope of the present inventive concept.

While the present inventive concept has been shown and described with reference to the embodiments thereof, it will be apparent to those of ordinary skill in the art that various changes in form and detail may be made thereto without departing from the spirit and scope of the present inventive concept.

What is claimed is:

1. A semiconductor stack structure comprising:
a plurality of semiconductor dies vertically stacked on each other; and
one or more dummy dies positioned between the plurality of semiconductor dies,
wherein each of the one or more dummy dies includes:
a dummy die base;
a first interconnection structure positioned on a first side of the dummy die base and including a plurality of first bonding pads, wherein the first bonding pads are positioned at substantially regular intervals; and
a second interconnection structure positioned on a second side of the dummy die base and including a plurality of second bonding pads, wherein the second bonding pads are positioned at substantially regular intervals.

2. The semiconductor stack structure of claim 1, wherein
a thickness of each of the dummy dies in a vertical direction is smaller than a thickness of each of the semiconductor dies in the vertical direction.

3. The semiconductor stack structure of claim 1, wherein
each of the dummy dies further includes through silicon vias, and
each of the through silicon vias electrically connects each of the second bonding pads to a corresponding first bonding pad of the first bonding pads.

4. The semiconductor stack structure of claim 1, wherein
the one or more dummy dies include a plurality of dummy dies, and
the semiconductor dies are alternately stacked with the dummy dies.

5. The semiconductor stack structure of claim 1, wherein
a difference between a maximum thickness and a minimum thickness of each of the dummy dies in a vertical direction is about 50 Å or less.

6. The semiconductor stack structure of claim 1, wherein
a number of stacked layers of the semiconductor dies and the one or more dummy dies is 12.

7. The semiconductor stack structure of claim 6, wherein
each of the dummy dies is on a fifth or seventh layer from a lowest layer of the stacked layers.

8. A semiconductor stack structure comprising:
a plurality of semiconductor dies vertically stacked; and
one or more dummy dies positioned between the plurality of semiconductor dies,
wherein each of the one or more dummy dies includes:
a dummy die base;
a first interconnection structure positioned on a first side of the dummy die base, wherein the first interconnection structure includes a plurality of first bonding pads positioned at substantially regular intervals and a first silicon insulating layer at least partially surrounding the first bonding pads; and
a second interconnection structure positioned on a second side of the dummy die base, wherein the second connection structure includes a plurality of second bonding pads positioned at substantially regular intervals and a second silicon insulating layer at least partially surrounding the second bonding pads,
wherein each of the semiconductor dies includes:
a semiconductor die base;
a third interconnection structure positioned on a first side of the semiconductor die base and positioned in a front side direction of the semiconductor die, wherein the third interconnection structure includes a plurality of third bonding pads and a third silicon insulating layer at least partially surrounding the third bonding pads; and a fourth interconnection structure positioned on a second of the semiconductor die base and positioned in a back side direction of the semiconductor die, wherein the fourth interconnection structure includes a plurality of fourth bonding pads and a fourth silicon insulating layer at least partially surrounding the fourth bonding pads.

9. The semiconductor stack structure of claim 8, wherein
surface roughnesses of each of the first interconnection structure and the second interconnection structure are about 10 Å or less.

10. The semiconductor stack structure of claim 8, wherein
each of the first bonding pads of each of the dummy dies is directly bonded to a corresponding second bonding pad among a plurality of second bonding pads of a neighboring dummy die or a corresponding fourth bonding pad among a plurality of fourth bonding pads of a neighboring semiconductor die.

11. The semiconductor stack structure of claim 8, wherein
each of the third bonding pads of each of the semiconductor dies is directly bonded to a corresponding second bonding pad among a plurality of second bonding pads of a neighboring dummy die or a corresponding fourth bonding pad among a plurality of fourth bonding pads of a neighboring semiconductor die.

12. The semiconductor stack structure of claim 8, wherein
the first silicon insulating layer of each of the dummy dies is directly bonded to a second silicon insulating layer of a neighboring dummy die, or a fourth silicon insulating layer of a neighboring semiconductor die.

13. The semiconductor stack structure of claim 8, wherein
the third silicon insulating layer of each of the semiconductor dies is directly bonded to a second silicon insulating layer of a neighboring dummy die or a fourth silicon insulating layer of a neighboring semiconductor die.

14. The semiconductor stack structure of claim 8, wherein
each of the semiconductor dies further includes through silicon vias, and
each of the through silicon vias electrically connects each fourth bonding pad of the fourth bonding pads to a corresponding third bonding pad of the third bonding pads.

15. A semiconductor package comprising:
an interposer;
a plurality of semiconductor stack structures disposed on the interposer;
a semiconductor structure disposed on the interposer; and
a molding material positioned on the interposer and covering the semiconductor stack structures and the semiconductor structure,
wherein each of the semiconductor stacked structures includes:
a plurality of first semiconductor dies vertically stacked on each other; and
one or more dummy dies positioned between the plurality of first semiconductor dies,
wherein each of the one or more dummy dies includes:
a dummy die base;
a first interconnection structure positioned on a first side of the dummy die base and including a plurality of first bonding pads, wherein the first bonding pads are positioned at substantially regular intervals; and
a second interconnection structure positioned on a second side of the dummy die base and including a plurality of second bonding pads, wherein the second bonding pads are positioned at substantially regular intervals.

16. The semiconductor package of claim 15, wherein
the semiconductor structure is positioned side by side with the semiconductor stack structures.

17. The semiconductor package of claim 15, wherein
the semiconductor structure is vertically positioned between the semiconductor stack structures and the interposer.

18. The semiconductor package of claim 15, wherein
the semiconductor stack structure includes a high bandwidth memory (HBM).

19. The semiconductor package of claim 15, wherein
the semiconductor structure includes a central processing unit (CPU) or a graphic processing unit (GPU).

20. The semiconductor package of claim 15, wherein
the molding material includes an epoxy molding compound (EMC).
